(19) United States
(12) Patent Application Publication
(10) Pub. No.: US 2006/0267701 A1
(43) Pub. Date: Nov. 30, 2006

(54) Method and system for dynamically calculating values for tuning of voltage-controlled crystal oscillators

(76) Inventor: Robert Eilers, Redmond, WA (US)

Correspondence Address: BROWNSTEIN HYATT & FARBER, 410 SEVENTEENTH STREET, 22ND FLOOR, DENVER, CO, 80202, US

(21) Appl. No.: 11/140,639

(22) Filed: May 27, 2005

(51) Int. Cl. H03B 5/32

(52) U.S. Cl. 331/158

(57) ABSTRACT

A voltage-controlled crystal oscillator (VCXO) being controllable by a tuning voltage, the VCXO having a crystal and an adjustable capacitor array. In one example, the VCXO includes an analog to digital converter converting the tuning voltage into corresponding digital values; a memory storing one or more parameters of the crystal and tuning profile; and a logic block receiving the digital values and the one or more parameters of the crystal and tuning profile, said logic block dynamically calculating one or more values for use in adjusting the adjustable capacitor array. In this way, the logic block can dynamically calculate and adjust the operations (i.e., the oscillation frequency) of the VCXO in real time.

### FIELD OF THE INVENTION

This invention relates, in general, to electronic circuits, and in particular to voltage-controlled crystal oscillator circuits.

### BACKGROUND OF THE INVENTION

Voltage-controlled crystal oscillators are used in numerous electronic circuit applications. Generally, a tuning voltage is utilized to adjust the oscillation frequency of a voltage-controlled crystal oscillator (VCXO). As the tuning voltage is adjusted, the oscillation frequency of the VCXO adjusts according to the particular implementation of the VCXO.

FIG. 1 illustrates an example of a digital voltage-controlled oscillator 10 is illustrated. In this example, the voltage-controlled oscillator 10 includes an oscillator circuit 12 which drives a crystal 14 having various crystal parameters such as parallel load resonant frequency, series resonant frequency, crystal shunt capacitance, crystal motional capacitance. The crystal oscillator circuit 12 may generally be configured in a feedback orientation, with capacitor arrays 16 utilized to electronically adjust the oscillation frequency.

For instance, a tuning voltage 18 may be processed by an analog to digital converter 20 whose output is utilized by a memory 22. In one example, the memory 22 may include a read only memory (ROM) or non-volatile memory (NV) containing a tuning profile for the voltage-controlled crystal oscillator.

Conventionally, the voltage-controlled crystal oscillator tuning profile stored in memory 22 is generated external to the system 10, and then programmed, hard coded, or burned into the memory 22. The memory 22 maps the values received from the analog digital converter 20 against the voltage-controlled crystal oscillator tuning profile stored within memory 22, and based on this mapping generates the values to set or adjust the adjustable capacitor arrays 16 in order to force the system 10 to oscillate at a desired frequency in response to tuning voltage 18. Essentially, the memory 22 converts the values received from the analog to digital converter 20 into values for adjusting the adjustable capacitor array 16 in order to achieve an oscillation frequency.

The system 10 of FIG. 1 has the benefit of allowing the programming of any arbitrary tuning profile into memory 22. However, system 10 has numerous drawbacks, including that the creation of the voltage-controlled crystal oscillator profile curve or map between voltages and appropriate capacitor adjustments is performed off chip, and cannot be easily altered without reprogramming the memory 22 with the particular profile. Moreover, if a large number of different profiles are stored in memory 22, then the size or total area of memory 22 can become large, which makes the use of the system 10 less desirable, as recognized by the present inventor.

As recognized by the present inventor, what is needed is a system for a voltage-controlled crystal oscillator which will provide dynamic calculations of the tuning profiles or values of the system so that the system can support a wide range of oscillation frequencies and various different crystals without the need for reprogramming the profile within the system. It is against this background that various embodiments of the present invention were developed.

### SUMMARY

In light of the above and according to one broad aspect of one embodiment of the present invention, disclosed herein a voltage-controlled crystal oscillator (VCXO) being controllable by a tuning voltage, the VCXO having a crystal and an adjustable capacitor array. In one example, the VCXO includes an analog to digital converter converting the tuning voltage into corresponding digital values; a memory storing one or more parameters of the crystal; and a logic block receiving the digital values and the one or more parameters of the crystal and desired tuning profile, said logic block dynamically calculating one or more values for use in adjusting the adjustable capacitor array. In this way, the logic block can dynamically calculate and adjust the operations (i.e., the oscillation frequency) of the VCXO in real time.

In one example, the logic block includes a calculation section and a control section and may include an arithmetic logic unit including sections for performing multiplication, addition, and other arithmetic functions. The logic block may include a state machine.

The logic block may calculate the one or more values for use in adjusting the adjustable capacitor array based in part upon the digital values, the one or more parameters of the crystal and the one or more parameters of the tuning profile. The one or more values for use in adjusting the adjustable capacitor array may include the address of the desired load capacitance within the array or other values.

The one or more parameters of the crystal may include a crystal shunt capacitance, a crystal motional capacitance, a parallel load resonant frequency, and/or a series resonant frequency. The one or more parameters of the tuning profile may include a starting crystal load capacitance, an ending crystal load capacitance, a desired starting frequency, a desired ending frequency, a desired starting ppm offset, a desired ending PPM offset, and/or desired pull range expressed in frequency or PPM. The memory may be a read only memory, a non-volatile memory, or a volatile memory.

According to another broad aspect of another embodiment of the present invention, disclosed herein is a method for controlling an oscillation frequency of a voltage-controlled crystal oscillator (VCXO) having a crystal. In one example, the method includes storing parameters of the crystal and tuning profile; converting an analog tuning voltage into a digital value; and dynamically computing capacitance values to apply to the VCXO to adjust the oscillation frequency, based on the digital value and parameters of the crystal. The method may also include adjusting an adjustable capacitor array using the capacitance values computed by the dynamic computing operation. In one example, the converting operation and the dynamically computing operation occur sequentially in real time.

In one example, the storing operation stores parameters of the crystal may include a crystal shunt capacitance. The storing operation stores parameters of the tuning profile may include a minimum crystal load capacitance, and/or a maximum crystal load capacitance.

In another example, the operation of dynamically computing capacitance values may include calculating an address for a capacitive array. The operation of storing may utilize a non-volatile memory or other type of conventional memory.

According to another broad aspect of another embodiment of the present invention, disclosed herein is an integrated circuit including a voltage-controlled crystal oscillator (VCXO) having an adjustable capacitor array, an analog to digital converter converting a tuning voltage into corresponding digital values, a memory storing one or more parameters of the crystal and tuning profile, and a logic block receiving the digital values and the one or more parameters of the crystal, said logic block dynamically calculating one or more values for use in adjusting the adjustable capacitor array.

The features, utilities and advantages of the various embodiments of the invention will be apparent from the following more particular description of embodiments of the invention as illustrated in the accompanying drawings.

### BRIEF DESCRIPTION OF THE DRAWINGS

FIG. 1 illustrates a conventional voltage-controlled crystal oscillator system including a memory storing the voltage-controlled crystal oscillator tuning profile and an analog to digital converter.

FIG. 2 illustrates an example of a voltage-controlled crystal oscillator system including an analog to digital converter, a tuning profile logic block/state machine, and a memory, in accordance with one embodiment of the present invention.

FIG. 3 illustrates an example of a logic block for calculating VCXO tuning profiles, in accordance with one embodiment of the present invention.

FIG. 4 illustrates an example of logical operations for dynamically calculating VCXO tuning profiles, in accordance with one embodiment of the present invention.

FIG. 5 illustrates an example of operations for a state machine implementation of an embodiment of the present invention.

FIG. 6 illustrates an example of various states of a state machine, in accordance with one embodiment of the present invention.

FIG. 7 illustrates an example of a graph of linear crystal frequency v. tuning voltage.

FIG. 8 illustrates an example of a graph of load capacitance v. tuning voltage.

FIG. 9 illustrates an example of a graph of frequency v. load capacitance.

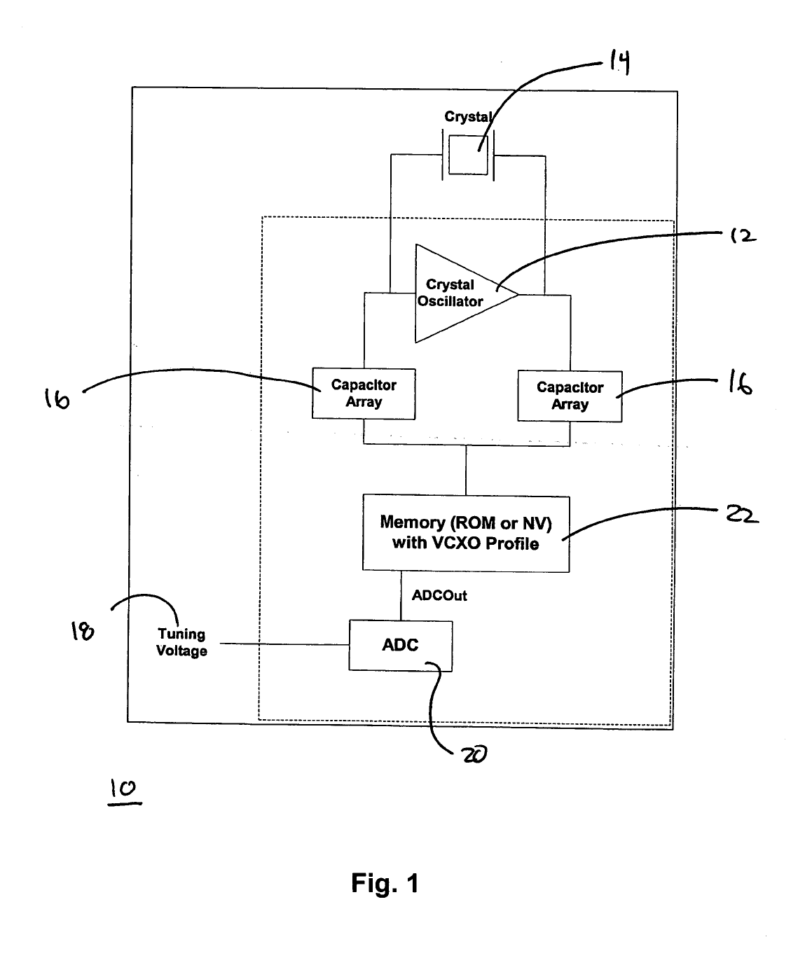

### DETAILED DESCRIPTION

Generally, embodiments of the present invention may provide for electronic tuning of a voltage-controlled crystal oscillator (VCXO) wherein a tuning profile or values are dynamically calculated based on various crystal parameters or other parameters. The tuning profile or values are dynamically calculated on chip, or within the system, without the need for large memories storing various profiles statically as is conventionally done. Hence, embodiments of the present invention may be utilized with various different crystals, and because of the dynamic tuning profile/value calculation provided by embodiments of the present invention, the oscillator system may be operated without the need for reprogramming a memory with new crystal profiles as is conventionally performed. Various embodiments of the present invention are described herein.

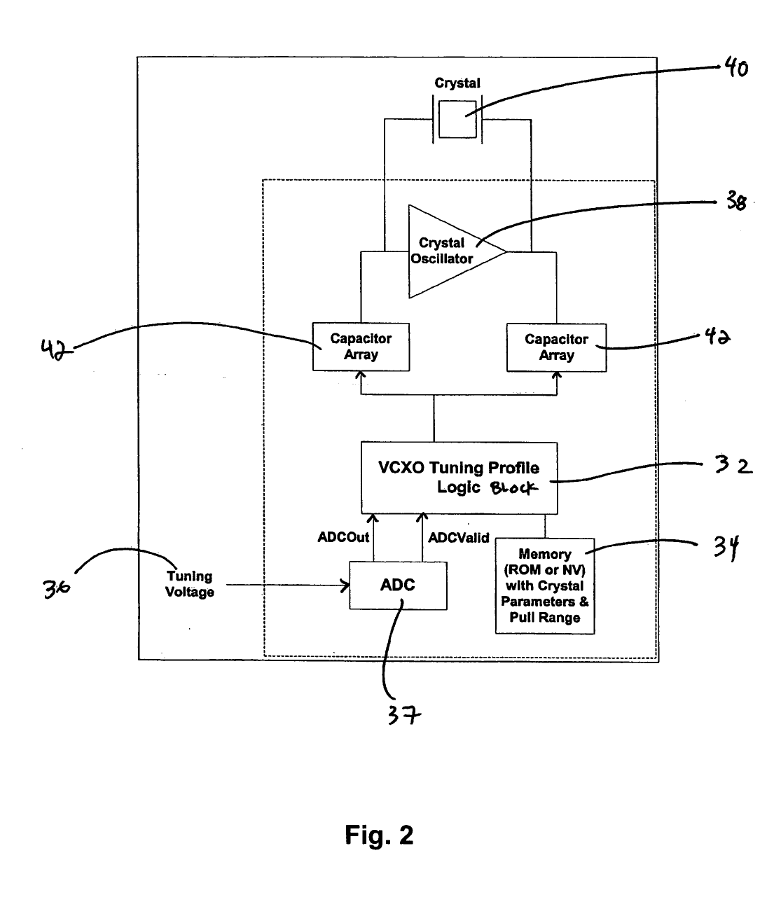

FIG. 2 illustrates an example of a voltage-controlled crystal oscillator system 30 in accordance with one embodiment of the present invention. The system 30 includes a logic block 32 and a memory 34. The logic block may be implemented using a state machine or other logic, and generally operates to calculate automatically tuning profiles and values needed for adjusting the system 30 in a dynamic fashion. For instance, the logic block 32 can automatically and dynamically compute voltage-controlled crystal oscillator tuning profiles such that the tuning profiles are linear, based upon crystal parameters and tuning profile parameters stored in memory 34, in one example. The logic block 32 can calculate a particular capacitance value or address in response to a tuning voltage value.

In one example, a tuning profile may be characterized as a mathematical plot or map between tuning voltages and capacitive values, or may include discrete values. A tuning profile may be used to specify a value to provide to an adjustable capacitor array 42 in order to adjust the oscillation frequency of the system 30 in response to tuning voltage 36.

In the example of FIG. 2, tuning voltage 36 is received by analog digital converter 37 which converts the tuning voltage into a digital value which is input into logic block 32. Logic block 32 receives the digital value from analog to digital converter 37, and is in communications with memory 34. Memory 34 may be implemented utilizing any type of memory, including conventional memories, such as ROM, non-volatile memories, or other memories.

Crystals may be characterized by their crystal shunt capacitance (C0), their crystal motional capacitance (C1), their parallel load resonant frequency (FL), and/or their series resonant frequency (FS). A tuning profile may be characterized by the starting crystal load capacitor value (i.e., CL1 which is the maximum load capacitance) and the ending crystal load capacitance value (i.e., CL2 which is the minimum load capacitance). The parallel load resonant frequency is the frequency of oscillation of the crystal when loaded with some value of load capacitance, CL. The crystal center frequency is the frequency of oscillation of the crystal when the nominal load capacitance of is applied to the crystal. The tuning profile of a crystal may be characterized by a minimum oscillation frequency and a maximum oscillation frequency; the minimum oscillation frequency may correspond with the maximum crystal load capacitance, while the maximum oscillation frequency may be associated with a minimum crystal load capacitance. Hence, it can be seen that the minimum and maximum crystal load capacitances can be used as parameters of a tuning profile.

Memory 34, in one example, stores crystal parameters and tuning profile parameters such as crystal shunt capacitance, crystal motional capacitance, crystal parallel load resonant frequency, crystal series resonant frequency, starting crystal load capacitance, ending crystal load capacitance, desired starting frequency, desired ending frequency, desired starting ppm offset, desired ending PPM offset, and/or desired pull range expressed in frequency or PPM.

Logic block 32 dynamically calculates a tuning profile or values based on the parameters stored in memory 34. When logic block 32 receives a tuning voltage digital value from analog to digital converter 37, the logic block generates values to control or adjust the capacitive arrays 42 in order to dynamically alter the oscillation frequencies of crystal oscillator 38 coupled with crystal 40.

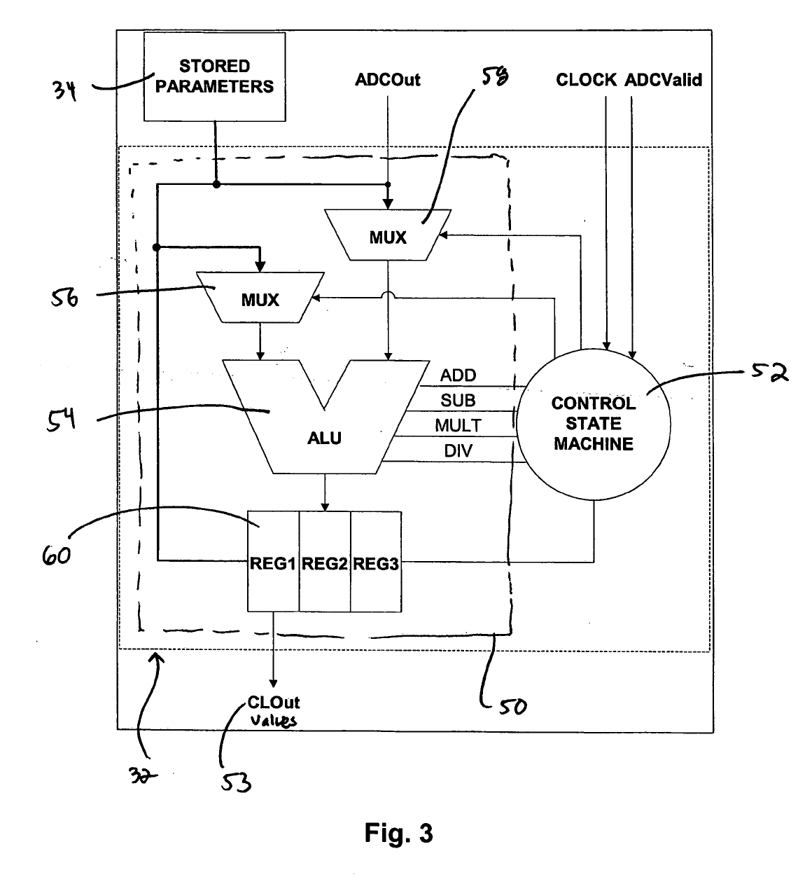

FIG. 3 illustrates an example of logic block 32 of FIG. 2, in accordance with one embodiment of the present invention. In this example, logic block 32 receives stored parameters from memory 34, as well as the output of analog to digital converter 37. A clock may also be utilized for controlling the operations of logic block 32.

In one example, logic block 32 may include a calculation section 50 and a control or state machine section 52. The calculation section 50 calculates the values 53 which are generated dynamically and are used, directly or indirectly, to adjust adjustable capacitor arrays 42 in system 30. Control section 52 may be provided in order to control the state of the calculation portion 50. It is understood that the calculation portion 50 and control portion 52 may be integrated into a single section or parts of an electronic system, depending upon the particular implementation.

In one example, the calculation section 50 may include an arithmetic logic unit 54 capable of performing various well known arithmetic functions. Such functions may include addition, subtraction, multiplication, division, or any other conventional functions such as loading, storing, shifting, bit testing, setting, clearing, or other functions conventionally performed by an arithmetic logic unit. A pair of multiplexers 56, 58 may also be provided, as well as a set of registers 60. In the example of FIG. 3, the control section 52 selects which inputs of multiplexers 56, 58 are fed into ALU 54. Control section 52 further instructs ALU 54 to perform the desired operations, such as add, subtract, multiply, divide, or other conventional functions. The results of the operations performed by ALU 54 may be stored in one or more of the plurality of registers 60.

It is understood that the example shown in FIG. 3 is provided for illustrative purposes only, and that various other implementations of the logic block are possible and contemplated by the present disclosure. Depending upon the implementation, the logic block 32 may be implemented using more sophisticated components, programmable logic, a portion of a logic core of a microprocessor or microcontroller, or may be implemented as one or more processes in a device having computational abilities.

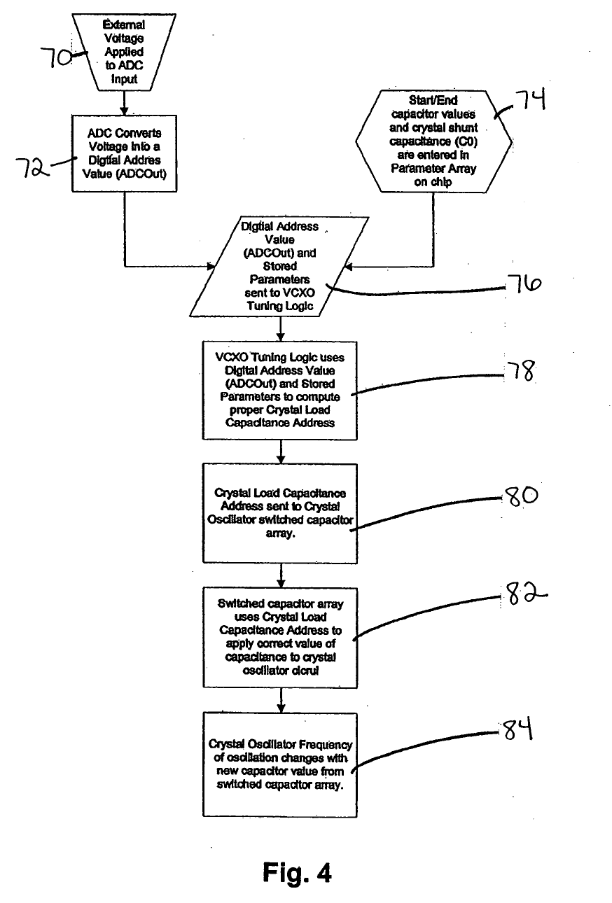

FIG. 4 illustrates an example of operations for controlling a voltage-controlled crystal oscillator, in accordance with one embodiment of the present invention.

At operation 70, a voltage, such as an external voltage or a control voltage for a voltage-controlled crystal oscillator, is applied to an analog to digital converter. At operation 72, the voltage is converted into a digital value, and this digital value can be used as an address.

At operation 74, which may occur before operations 70, 72, capacitor parameters are stored in the memory. This operation may include capacitor parameters such as start/end capacitor values (i.e., maximum and minimum crystal load capacitor values) and crystal shunt capacitance (i.e., C0) are entered in parameter array on chip.

At operation 76, the digital address value (shown as ADCOut) and the stored parameters are sent to VCXO tuning logic. This operation may include the data from operations 72 and 74 being sent to the logic block.

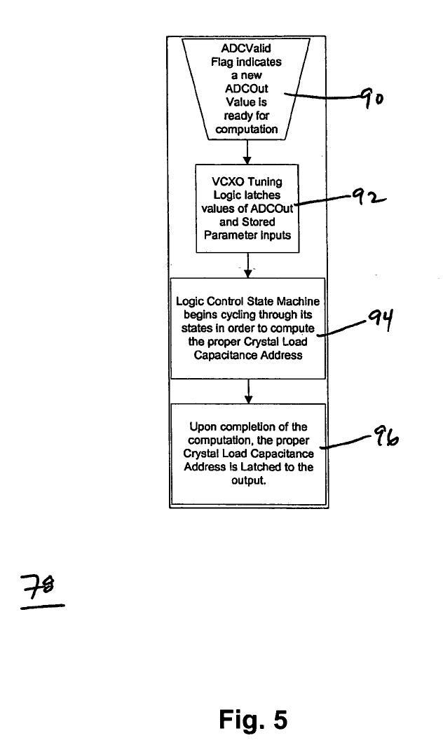

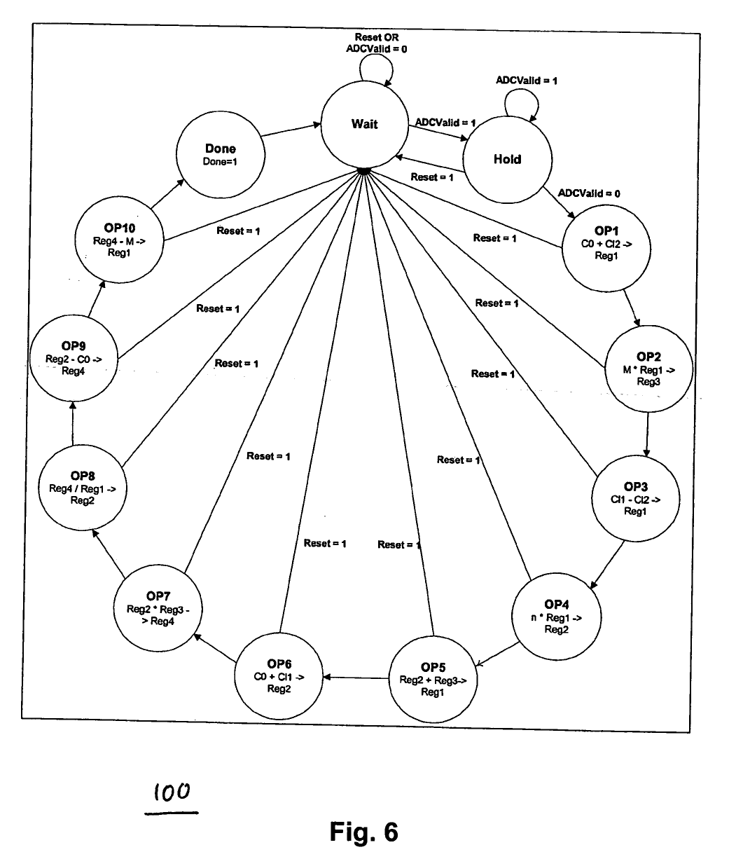

At operation 78, the VCXO tuning logic uses the digital address value (ADCOut) and stored parameters to compute a proper crystal load capacitance value. In one example, the computation performed at operation 78 generates an address for the crystal load capacitance, although other values can be computed. One example of operation 78 is further described by the operations 90-96 illustrated in FIG. 5. A specific example of a calculation and a calculation state machine are illustrated in FIG. 6 and described herein, however, it is understood that these specific example described herein is not intended to limit the scope of the present invention.

In one example, at operation 80, the crystal load capacitance address is sent to the adjustable capacitor array. At operation 82, the adjustable capacitor array uses the crystal load capacitance address to apply the correct value of capacitance to a crystal oscillator circuit. At operation 84, the crystal oscillator frequency of oscillation changes with the new capacitor value from the adjustable capacitor array.

FIG. 5 illustrates an example of operations to compute the crystal load capacitance address, shown as operation 78 in FIG. 4. In one embodiment, operations 90-96 may be implemented in a state machine implementation or in another form for controlling the calculation section of the logic block.

In one example, at operation 90, an ADCValid flag indicates a new ADC value (ADCOut) is ready for computation, Operation 90 may be in response to receiving a new value from an analog-to-digital converter (i.e., a new tuning voltage has been detected). At operation 92, the VCXO tuning logic latches values of ADCOut and stored parameter inputs. At operation 94, the logic control state machine begins cycling through its states in order to compute the proper crystal load capacitance values or addresses. At operation 96, upon completion of the computation, the proper crystal load capacitance address is latched to the output.

In one embodiment of the present invention, the crystal parameters are read and utilized to create a tuning curve, and as the data from the analog to digital converter is received, a corresponding value from the tuning curve is read or mapped so as to produce the corresponding load capacitance value needed to achieve the desired tuning corresponding with the tuning voltage received.

In another embodiment of the present invention, a capacitance value is generated each time a new value from the analog to digital converter (i.e., an ADC digital address ADCOut) is presented to the state machine. Hence, in this implementation, the crystal and tuning profile parameters such as the crystal shunt capacitance, minimum and maximum crystal load capacitances are taken into account within the calculation of the load capacitance for the particular address supplied by the analog to digital converter. In this example, there may not need to be a prior calculation of a tuning profile, as the equation indicated below can generate the needed capacitance calculation without having to reference a particular tuning profile.

FIG. 6 illustrates an example of a state diagram having a plurality of states which may be utilized for calculation of the appropriate capacitance value for tuning the voltage-controlled crystal oscillator, in accordance with one embodiment of the present invention. The states are labeled OP1, OP2, OP3—OP10, which reflects a plurality of operations for implementing the equation shown below. It is understood that these states could be implemented in different manners in order to realize the equation implemented below, or alternatively a different equation or computation could be performed in order to calculate a capacitance value.

In one example, at state OP1, register 1 is loaded with the sum of C0 plus CL2. At state OP2, register 3 is loaded with the product of M times the contents of register 1. At state OP3, register 1 is loaded with the difference between CL1 and CL2. At state OP4, register 2 is loaded with the product of n times the contents of register 1. At state OP5, register 1 is loaded with the sum of the contents of register 2 and register 3. At state OP6, register 2 is loaded with the sum of C0 plus CL1. At state OP7, register 4 is loaded with the product of register 2 times register 3. At state OP8, register 2 is loaded with the result of a division operation, register 4 divided by register 1. At state OP9, register 4 is loaded with the difference of register 2 minus C0. At state OP10, register 1 is loaded with the difference between register 4 minus M, at which point the state machine is complete for this calculation.

In this example, the state machine realizes the following equation to produce a linear VCXO tuning curve and discrete values for use by the adjustable capacitor array:

$${C}_{Ln} = \frac{( {C}_{0} + {C}_{L 1} ) ( M ) ( {C}_{0} + {C}_{L 2} )}{( M ) ( {C}_{0} - {C}_{L 2} ) + n ( {C}_{L 1} - {C}_{L 2} )} - {C}_{0} - ( M )$$

where M=ADC resolution−1

n=current ADC digital address (ADCOut)

C0=crystal shunt capacitance normalized to crystal load capacitor array values+M

CL1=starting crystal load capacitor value normalized to crystal load capacitor array values

CL2=ending crystal load capacitor value normalized to crystal load capacitor array values

Additional inputs and outputs may include:

ADCValid: Input signal from the ADC indicating a new value from the ADC is ready to process. This initiates the state machine computation process.

Done: Output signal indicating computation process is complete and a new capacitor load value is available.

The following describes the operation of each state and provides a snap shot of the contents of each register. Note that it is implied for each OPx state that the proper ALU operation flag is asserted (ADD, SUB, MULT, DIV), the proper mux select line is asserted (Mux1Ct1, Mux2Ct1), and the proper register load flag is asserted (REG1Load, REG2Load, Reg3Load, Reg4Load). It is also implied that when Reset=1, all states will return to the Hold State on the next clock transition.

Hold State: Reset State:
Next State: IF (ADCValid=1) THEN Wait State ELSE Hold State
Reg1: 0
Reg2: 0
Reg3: 0
Reg4: 0

Wait State: Initialize Regs
Next State: IF (ADCValid=1) THEN Hold State ELSE OP1
Reg1: 0
Reg2: 0
Reg3: 0
Reg4: 0

Op1:CL2+C0→Reg1
Reg1: CL2+C0
Reg2: 0
Reg3: 0
Reg4: 0

Op2: M*Reg1→Reg3
Reg1: CL2+C0
Reg2: 0
Reg3: M*(CL2+C0)
Reg4: 0

Op3: CL1−Cl2→Reg1
Reg1: CL1−CL2
Reg2: 0
Reg3: M*(CL2+C0)
Reg4: 0

Op4: n*Reg1→Reg2
Reg1: CL1−CL2
Reg2: n*(CL1−CL2)
Reg3: M*(CL2+C0)
Reg4: 0

Opt5: Reg2+Reg3→Reg1
Reg1: n*(CL1−CL2)+M*(CL2+C0)
Reg2: n*(CL1−CL2)
Reg3: M*(CL2+C0)
Reg4: 0

Op6: C0+CL1→Reg2
Reg1: n*(CL1−CL2)+M*(CL2+C0)
Reg2: C0+CL1
Reg3: M*(CL2+C0)
Reg4: 0

Op7: Reg2 * Reg3→Reg4
Reg1: n*(CL1−CL2)+M*(CL2+C0)
Reg2: C0+CL1
Reg3: M*(CL2+C0)
Reg4: (C0+CL1)*(M*(CL2+C0))

Op8: Reg4/Reg1→Reg2
Reg1: n*(CL1−CL2)+M*(CL2+C0)
Reg2: ((C0+CL1)*(M*(CL2+C0)))/(n*(CL1−CL2)+M*(CL2+C0))
Reg3: M*(CL2+C0)
Reg4: (C0+CL1)*(M*(CL2+C0))

Op9: Reg2−C0→Reg4
Reg1: n*(CL1−CL2)+M*(CL2+C0)
Reg2: ((C0+CL1)*(M*(CL2+C0)))/(n*(CL1−CL2)+M*(CL2+C0))
Reg3: M*(CL2+C0)
Reg4: ((C0+CL1)*(M*(CL2+C0)))/(n*(CL1−CL2)+M*(CL2+C0) )−C0

OP10: Reg4−m→Reg1
Reg1: ((C0+CL1)*(M*(CL2+C0)))/(n*(CL1−CL2)+M*(CL2+C0) )−C0−M
Reg2: ((C0+CL1)*(M*(CL2+C0)))/(n*(CL1−CL2)+M*(CL2+C0))
Reg3: M*(CL2+C0)
Reg4: ((C0+CL1)*(M*(CL2+C0)))/(n*(CL1−CL2)+M*(CL2+C0))−C0

Done: Done=1;
Final value latched to output Cload register from Reg1
Reg1: ((C0+CL1)*(M*(CL2+C0)))/(n*(CL1−CL2)+M*(CL2+C0))−C0−M
Reg2: ((C0+CL1)*(M*(CL2+C0)))/(n*(CL1−CL2)+M*(CL2+C0))
Reg3: M*(CL2+C0)
Reg4: ((C0+CL1)*(M*(CL2+C0)))/(n*(CL1−CL2)+M*(CL2+C0))−C0

The analog digital converter resolution is a function of the number of bits of the analog to digital conversion process. For example, for an 8 bit analog to digital converter, the amount of resolution is 2ˆ8 or 256, and accordingly, M=256−1=255. The current ADC digital address (ADCOut) for an 8 bit analog to digital converter can range from 0 to 255.

The logic may map from an x-bit ADC to a y-bit capacitor array. That is, the resolution of the ADC and the capacitor array does not have to be equivalent and the logic may properly map a lower-bit ADC to a higher-bit capacitor array and vice versa.

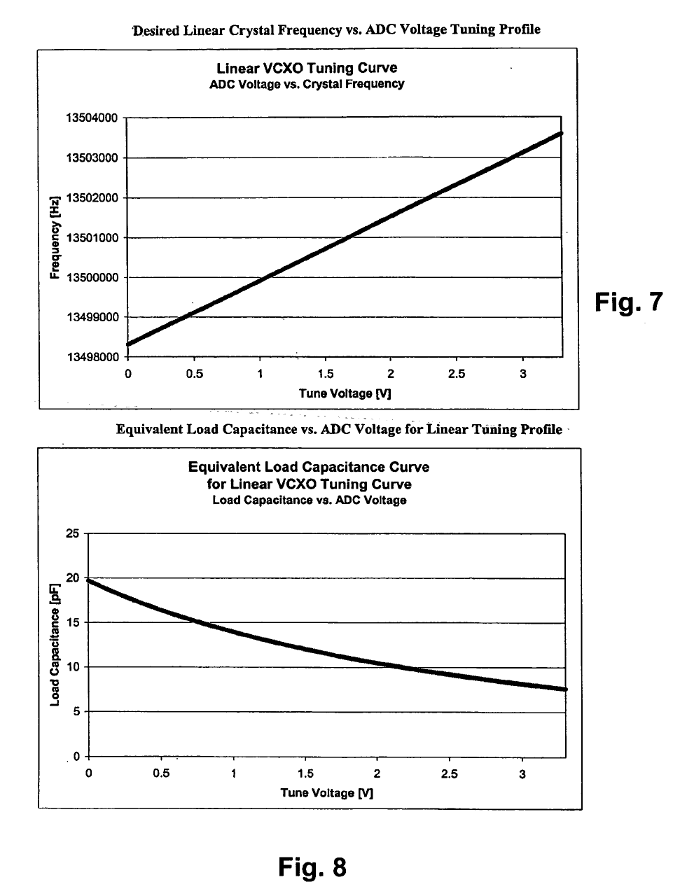

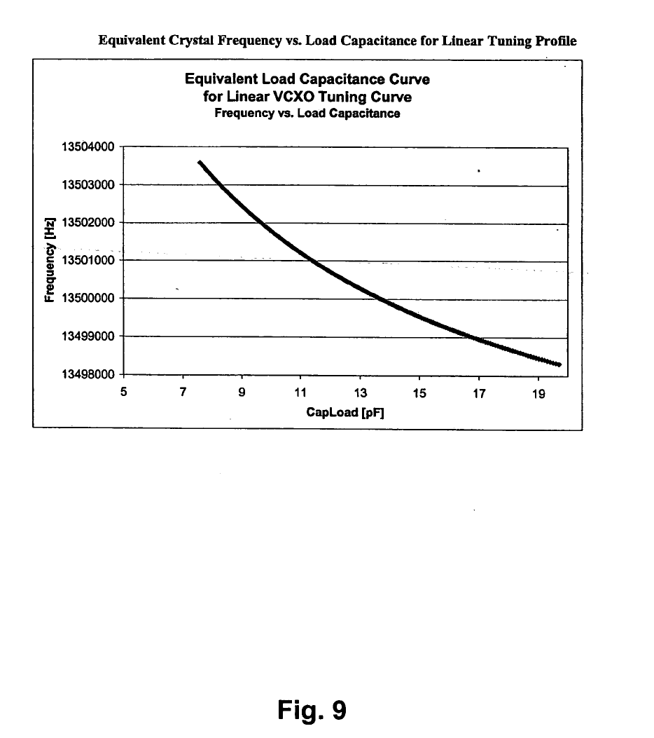

In one example, a very linear VCXO tuning profile is sought to be achieved. However, since the capacitance vs. frequency relationship of the crystal oscillator system is non-linear, a non-linear mapping of values from the ADC to the capacitor array may be employed. Stated differently, for any given desired shape of the VCXO tuning profile (linear or non-linear), a non-linear mapping of values from the ADC value to the capacitor array can be computed. FIG. 7 illustrates an example of a graph of a desired linear crystal frequency v. tuning voltage (ADC value), in one example. FIG. 8 illustrates an equivalent profile expressed in an example of a graph of load capacitance v. tuning voltage. FIG. 9 illustrates an equivalent profile expressed in an example of a graph of frequency v. load capacitance.

While examples of embodiments of the present invention have been described herein with reference to crystal oscillators, it is understood that embodiments of the invention could be utilized with other types of oscillators, such as RC oscillators, SAW oscillators, LC tank oscillators, etc.

Embodiments of the present invention may be used in various semiconductors, memories, processors, controllers, integrated circuits, logic or programmable logic, clock circuits, and the like.

While the methods disclosed herein have been described and shown with reference to particular operations performed in a particular order, it will be understood that these operations may be combined, sub-divided, or re-ordered to form equivalent methods without departing from the teachings of the present invention. Accordingly, unless specifically indicated herein, the order and grouping of the operations is not a limitation of the present invention.

It should be appreciated that reference throughout this specification to “one embodiment” or “an embodiment” or “one example” or “an example” means that a particular feature, structure or characteristic described in connection with the embodiment may be included, if desired, in at least one embodiment of the present invention. Therefore, it should be appreciated that two or more references to “an embodiment” or “one embodiment” or “an alternative embodiment” or “one example” or “an example” in various portions of this specification are not necessarily all referring to the same embodiment. Furthermore, the particular features, structures or characteristics may be combined as desired in one or more embodiments of the invention.

It should be appreciated that in the foregoing description of exemplary embodiments of the invention, various features of the invention are sometimes grouped together in a single embodiment, figure, or description thereof for the purpose of streamlining the disclosure and aiding in the understanding of one or more of the various inventive aspects. This method of disclosure, however, is not to be interpreted as reflecting an intention that the claimed inventions require more features than are expressly recited in each claim. Rather, as the following claims reflect, inventive aspects lie in less than all features of a single foregoing disclosed embodiment, and each embodiment described herein may contain more than one inventive feature.

While the invention has been particularly shown and described with reference to embodiments thereof, it will be understood by those skilled in the art that various other changes in the form and details may be made without departing from the spirit and scope of the invention.

What is claimed is:

1. A voltage-controlled crystal oscillator (VCXO) being controllable by a tuning voltage, the VCXO having a crystal and an adjustable capacitor array, comprising:
an analog to digital converter converting the tuning voltage into corresponding digital values;
a memory storing one or more parameters of the crystal; and
a logic block receiving the digital values and the one or more parameters of the crystal, said logic block dynamically calculating one or more values for use in adjusting the adjustable capacitor array.

2. The voltage-controlled crystal oscillator of claim 1, wherein the memory is a read only memory.

3. The voltage-controlled crystal oscillator of claim 1, wherein the memory is a non-volatile memory.

4. The voltage-controlled crystal oscillator of claim 1, wherein the memory stores on or more parameters of a tuning profile.

5. The voltage-controlled crystal oscillator of claim 1, wherein the logic block includes a calculation section and a control section.

6. The voltage-controlled crystal oscillator of claim 1, wherein the logic block includes an arithmetic logic unit including a multiplier and divider section.

7. The voltage-controlled crystal oscillator of claim 1, wherein the logic block includes a state machine.

8. The voltage-controlled crystal oscillator of claim 1, wherein the logic block calculates the one or more values for use in adjusting the adjustable capacitor array based in part upon the digital values and the one or more parameters of the crystal.

9. The voltage-controlled crystal oscillator of claim 1, wherein the one or more values for use in adjusting the adjustable capacitor array include an address of one or more load capacitance values.

10. The voltage-controlled crystal oscillator of claim 1, wherein the one or more parameters of the crystal include a crystal shunt capacitance.

11. The voltage-controlled crystal oscillator of claim 4, wherein the one or more parameters of the tuning profile include a starting crystal load capacitance.

12. The voltage-controlled crystal oscillator of claim 4, wherein the one or more parameters of the tuning profile include an ending crystal load capacitance.

13. A method for controlling an oscillation frequency of a voltage-controlled crystal oscillator (VCXO) having a crystal, comprising:
storing parameters of the crystal;
storing parameters of a tuning profile;
converting an analog tuning voltage into a digital value; and
dynamically computing capacitance values to apply to the VCXO to adjust the oscillation frequency, based on the digital value and parameters of the crystal and the tuning profile.

14. The method of claim 13, further comprising:
adjusting an adjustable capacitor array using the capacitance values computed by the dynamic computing operation.

15. The method of claim 13, wherein the storing operation stores parameters of the crystal including a crystal shunt capacitance.

16. The method of claim 13, wherein the storing operation stores parameters of the tuning profile including a minimum crystal load capacitance.

17. The method of claim 13, wherein the storing operation stores parameters of the tuning profile including a maximum crystal load capacitance.

18. The method of claim 13, wherein the operation of dynamically computing capacitance values includes calculating an address for a capacitive array.

19. The method of claim 13, wherein the operation of storing utilizes a non-volatile memory.

20. The method of claim 13, wherein the converting operation and the dynamically computing operation occur sequentially in real time.

21. An integrated circuit, comprising:
a voltage-controlled crystal oscillator (VCXO) having
an adjustable capacitor array;
an analog to digital converter converting a tuning voltage into corresponding digital values;
a memory storing one or more parameters of a crystal; and
a logic block receiving the digital values and the one or more parameters of the crystal, said logic block dynamically calculating one or more values for use in adjusting the adjustable capacitor array.
